(19) United States
(12) Patent Application Publication
(10) Pub. No.: US 2026/0037148 A1
(43) Pub. Date: Feb. 5, 2026

(54) DETERMINING HEALTH OF WORDLINES FOR CONTINUED USER DATA PROGRAMMING

(71) Applicant: Microchip Technology Incorporated, Chandler, AZ (US)

(72) Inventors: Saswati DAS, Milpitas, CA (US); Pitamber SHUKLA, San Jose, CA (US); Srinivas YELISETTI, Fremont, CA (US); Nian Niles YANG, Mountain View, CA (US)

(21) Appl. No.: 19/034,553

(22) Filed: Jan. 22, 2025

Related U.S. Application Data
(60) Provisional application No. 63/677,406, filed on Jul. 30, 2024.

(51) Int. Cl. G06F 3/06

(52) U.S. Cl. CPC G06F 3/0619; G06F 3/0634; G06F 3/0659; G06F 3/0679

(57) ABSTRACT

In some implementations, a controller may determine a health of a last programmed wordline of a virtual block during a bootup process of a storage device that includes the virtual block, wherein the virtual block is an open state, wherein the virtual block includes user data, and wherein the health of the last programmed wordline is determined using a first machine learning model. The controller may determine, based on the health of the last programmed wordline, a health of a next unprogrammed wordline of the virtual block during the bootup process, wherein the health of the next unprogrammed wordline is determined using a second machine learning model. The controller may program additional user data on the virtual block after the bootup process, wherein the additional user data is programmed based on determining the health of the last programmed wordline and based on determining the health of the next unprogrammed wordline.

### CROSS-REFERENCE TO RELATED APPLICATION

This Patent Application claims priority to Provisional Patent Application No. 63/677,406, filed on Jul. 30, 2024, and entitled “DETERMINING HEALTH OF WORDLINES FOR CONTINUED USER DATA PROGRAMMING.” The disclosure of the prior Provisional Patent Application is considered part of and is incorporated by reference into this Patent Application.

### FIELD

The present disclosure generally relates to programming user data on a virtual block and, for example, to programming user data on the virtual block based on health of wordlines of the virtual block.

### BACKGROUND

A non-volatile memory device may include a storage device that may store and retain data without external power supply. One example of a storage device is a NAND flash memory device. A solid state drive (SSD) may include multiple non-volatile memory devices. A non-volatile memory device (or a die of the non-volatile memory device) may include multiple planes. A plane may include multiple blocks and a block may include multiple wordline. A wordline may include one or more pages.

In some situations, the multiple non-volatile memory devices (or dies of the multiple non-volatile memory devices) may form a virtual block (VB). The VB is a collection of blocks (e.g., memory blocks) across all logical unit numbers (LUNs). A VB has a size that varies according to number of bad blocks. For example, if no bad blocks, the size=(#Channels)×(#Targets)×(#LUNs)×(Physical Block Size). The VB includes multiple virtual pages. A virtual page is a collection of pages across all LUNs in a VB.

Typically, a reliability of the SSD decreases as the age of the non-volatile memory device increases. The decrease in reliability leads to an increase in read errors.

### SUMMARY

A method comprising: determining a health of a last programmed wordline of a virtual block during a bootup process of a storage device that includes the virtual block, wherein the virtual block is an open state, wherein the virtual block includes user data, and wherein the health of the last programmed wordline is determined using a first machine learning model; determining, based on the health of the last programmed wordline, a health of a next unprogrammed wordline of the virtual block during the bootup process, wherein the health of the next unprogrammed wordline is determined using a second machine learning model; and programming additional user data on the virtual block after the bootup process, wherein the additional user data is programmed based on determining the health of the last programmed wordline and based on determining the health of the next unprogrammed wordline.

A system comprising: a controller to: determine a health of a last programmed wordline of a virtual block during a bootup process of a storage device that includes the virtual block, wherein the bootup process occurs after a power cycle, wherein the virtual block is an open state, and wherein the virtual block includes user data; determine, based on the health of the last programmed wordline, a health of a next unprogrammed wordline of the virtual block during the bootup process; and program additional user data on the virtual block after the bootup process, wherein the additional user data is programmed based on determining the health of the last programmed wordline and based on determining the health of the next unprogrammed wordline.

A non-transitory computer-readable medium storing a set of instructions, the set of instructions comprising: one or more instructions that, when executed by one or more processors of a controller, cause the controller to: determine a health of a last programmed wordline of a virtual block during a bootup process of a storage device that includes the virtual block, wherein the bootup process occurs after a power cycle, wherein the virtual block is an open state, and wherein the virtual block includes user data; determine, based on the health of the last programmed wordline, a health of a next unprogrammed wordline of the virtual block during the bootup process; and program additional user data on the virtual block after the bootup process, wherein the additional user data is programmed based on determining the health of the last programmed wordline and based on determining the health of the next unprogrammed wordline.

### BRIEF DESCRIPTION OF THE DRAWINGS

FIG. 1 is a block diagram showing an example of a solid state drive (SSD), in accordance with the present disclosure.

FIG. 2 is a block diagram showing another example of an SSD, in accordance with the present disclosure.

FIG. 3 is a schematic block diagram showing an example associated with using machine learning for determining health of wordlines for continued user data programming, in accordance with the present disclosure.

FIG. 4 is a flow chart showing an example of a process for determining health of wordlines for continued user data programming, in accordance with the present disclosure.

FIG. 5 is a flow chart showing another example of a process for determining health of wordlines for continued user data programming, in accordance with the present disclosure.

### DETAILED DESCRIPTION

The following detailed description of example implementations refers to the accompanying drawings. The same reference numbers in different drawings may identify the same or similar elements.

A solid state drive (SSD) may provide data regarding the SSD to a host device associated with the SSD. An SSD may include multiple non-volatile memory devices. The multiple non-volatile memory devices (or dies of the multiple non-volatile memory devices) may form a virtual block (VB). The VB is a collection of blocks (e.g., memory blocks) across multiple logical unit numbers (LUNs).

Blocks, in the VB, may have the same program/erase (P/E) cycles. A controller of the SSD may maintain separate pools of VBs for user data and system data. System data may be stored on single layer charge (SLC) blocks due to the high reliability requirement for the system data whereas user data may be stored on triple layer cell (TLC) blocks. Some blocks may be reserved per die to be replacements for bad blocks.

Typically, a reliability of the SSD decreases as the age of the non-volatile memory device increases. The decrease in reliability leads to an increase in read errors.

A VB, in an open state, may remain open for an extended time (e.g., for a time threshold) without any data being written to the VB. Under this condition, an immediate unprogrammed wordline (WLₙ₊₁) may be impacted by data retention degradation in conjunction with an erase bake condition. As used herein, an “erase bake condition” may refer to a portion of block (e.g., a wordline) being subjected to program errors (or program failures) as a result of the portion of the block remaining unprogrammed for an extended period of time. As used herein, an “erase bake condition” may refer to a scenario under which a NAND block (which is in an erase state) goes through a data retention condition which will result in errors, particularly for a lowest state valley. All the physical wordlines, of the NAND block, may be in the erase state. Subsequent unprogrammed wordlines (WLₙ₊₂ and onwards) may be impacted by the erase bake condition.

If a partial written block remains inactive without any further programming operations for a long time, the immediate unprogrammed wordline (WLₙ₊₁) may be subjected to data retention and an erase bake condition. Additionally, the subsequent unprogrammed wordlines (WLₙ₊₂ onwards) may be subject to an erase bake condition, thereby making the unprogrammed wordlines more error prone to program and read errors. A last written wordline may also be impacted by data retention issues.

Existing firmware (FW) algorithms (e.g., algorithms used by the controller) do not perform any check on unprogrammed wordlines and continue writing to the virtual open block, even if the VB is in an open state and has not been programmed for a very long time. Programming the VB in this manner can make the unprogrammed wordlines susceptible to program errors, read errors, or a combination of program errors and read errors. Therefore, programming the VB in this manner can reduce the reliability of the drive.

If a program or read error occurs on a physical block of the open VB, existing FW solutions mark the multiplane block of the VB as a bad block (e.g., a corrupted block). For example, existing FW solutions mark multiplane blocks, of the VB, as bad blocks (e.g., corrupted blocks). Marking the multiple blocks of the VB as bad blocks can reduce the over provisioning (OP) of the SSD and increase write amplification. Also, in the event of a program error, existing FW solutions close the open VB and trigger an urgent garbage collection operation for the open VB to reduce the impact of program disturb caused by the program error. Closing the open VB and triggering the urgent garbage collection can further increase write amplification. Write amplification not only reduces write performance but also reduces the life of the SSD by increasing P/E cycles of the blocks.

If the SSD undergoes a power cycle, it is currently difficult to know how long the drive was powered off and how long the VB had been in an open state. As such, to avoid an erase bake condition (of the VB in the open state) after a bootup process, existing FW solutions close the open VB and move valid data to a new VB. Closing the open VB and moving the valid data to a new VB increases a time to ready (TTR) for the SSD.

After moving the data to the new block, the VB is freed and eventually erased to program new data. Over time, multiple open block erase operations will reduce the reliability of the VB. Open block erase can cause deep erase on unprogrammed wordlines and shallow erase on programmed wordlines.

Implementations described herein are directed to a technical solution to the technical problem of data retention degradations and erase bake conditions explained herein. Additionally, implementations described herein are directed to a technical solution of using machine learning (ML) algorithms to periodically check the health of the immediate unprogrammed wordline in a partially written open VB, which is not programmed for a specific period and, hence, may be impacted by an open block bake condition. An “open block bake condition” may be used to refer to a combination of an erase bake condition and data retention degradation. An “open block” may refer to a NAND block which includes programmed wordlines and unprogrammed/erase wordlines. For example, in the NAND block, there may be “N” wordlines. If we program to the “n” wordlines in the NAND block, then “N-n” wordlines will be in the erase state. Now, till wordline n (the wrodlines with the written data), we will observe the loss of the electron (which is also referred to as data retention degradation). The wordline n+1 will observe the gain of the electrons from the wordline n (last written wordline) and also the effect of the erase bake as wordline n+1 is the 1^{st} unprogrammed wordline. Moving from wordline n+1 which is wordline n+2 to wordline N, mostly we will see the impact of the bake on the erase wordlines. Based on the health of the immediate unprogrammed wordline, a controller may continue writing user data to unprogrammed wordlines of the partially open VB when a host write command is issued, based on the health check of the immediate unprogrammed wordlines. Continuing to write user data in this manner may significantly reduce program and read errors on the SSD, reduce uncorrectable bit error rate (UBER) and improve the reliability of the SSD.

By virtue of intelligent decision making, implementations described herein avoid unnecessary reduction of effective OP of the SDD in case of program and read errors and reduction of unnecessary urgent garbage collection operations in the event of program errors, thereby reducing write amplification of the SSD. By reducing write amplification and conserving OP, implementations described herein maintain sustained write performance, avoid reducing user space of the SSD, and significantly improves the lifetime of the SSD.

By using ML algorithms (e.g., ML models) to check the health of the last programmed wordline of an open VB after a bootup process and by avoiding a garbage collection operation during the bootup process if the last programmed wordline is healthy, implementations described herein may reduce the bootup time (e.g., time to ready of the SSD).

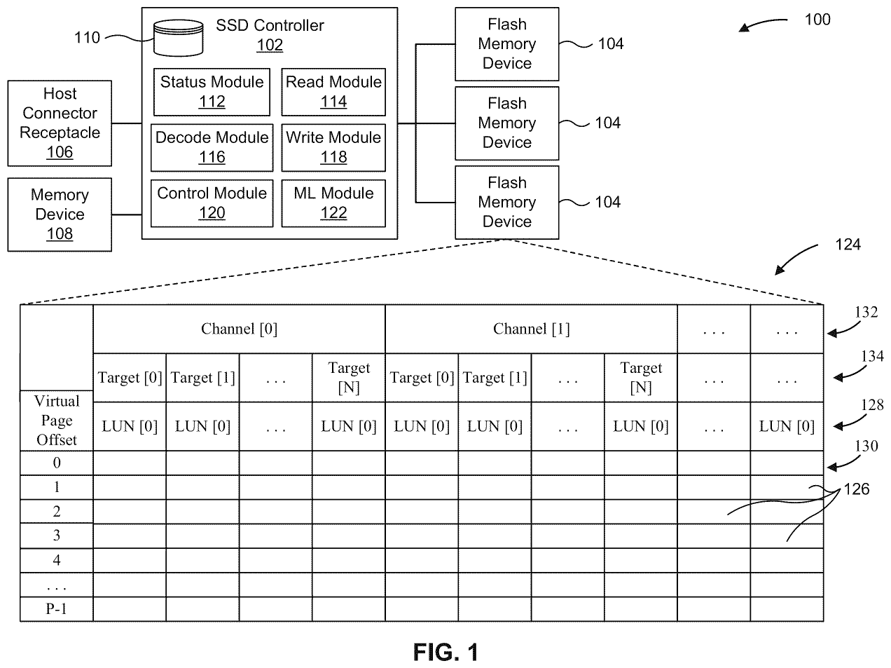

FIG. 1 is a block diagram showing an example of an SSD 100, in accordance with the present disclosure. SSDs may use standard read instructions (e.g., READ or READ PAGE instruction) to perform a read of a memory cell at a default threshold voltage within each threshold voltage region required to define a bit of the memory cell. Single Level Cell (SLC) flash memory devices store a single bit of information in each cell and only require a read in a single threshold voltage region (the threshold voltage region is the region that extends between the center of the voltage distribution for a 1 and the center of the voltage distribution for a 0) to identify the value of a bit (whether the cell is storing a 1 or a 0). Multi-level cell (MLC) flash memory devices store two bits of information in each cell, triple level cell (TLC) flash memory devices store three bits of information in each cell, quad level cell (QLC) flash memory devices store four bits of information in each cell and penta level cell (PLC) flash memory devices store five bits of information in each cell.

Some SSD's use threshold-voltage-shift reads for reading flash memory devices together with a low density parity check (LDPC) Hard Decoder to correct the bit errors in order to obtain low levels of UBER required for client and enterprise SSD's. Threshold-voltage-shift reads are performed by sending a threshold-voltage-shift read instruction to a flash memory device that is to be read. One or more threshold-Voltage-Shift Offset (TVSO) values are sent with the threshold-voltage-shift read instruction. The TVSO value indicates the amount by which the threshold voltage that is used to perform the read is to be offset from a corresponding default threshold voltage that is specified by the manufacturer of the flash memory device. If a read instruction faces a LDPC hard decoding failure, a threshold-voltage-shift read recovery process for MLC, TLC, QLC, and PLC flash memory devices send multiple TVSO values to the flash memory device in order to perform the error correction for the read.

The SSD 100 is shown in FIG. 1 to include an SSD controller 102 coupled to a plurality of flash memory devices 104 for storing data. In some embodiments, the flash memory devices 104 are NAND devices and the SSD 100 includes one or more circuit boards onto which a host connector receptacle 106, the SSD controller 102, and the flash memory devices 104 are attached. The SSD 100 may also include one or more memory devices 108, such as a Dynamic Random Access Memory (DRAM), that may be a separate integrated circuit device attached to the one or more circuit boards, and is electrically coupled to the SSD controller 102.

The SSD controller 102 is configured to receive read and write instructions from a host computer through the host connector receptacle 106 and to perform program operations, erase operations, and read operations on memory cells of flash memory devices 104 to complete the instructions from the host computer. For example, upon receiving a write instruction from the host computer via host connector receptacle 106, the SSD controller 102 is operable to store data in the SSD 100 by performing program operations (and when required, erase operations) to program codewords into one or more flash memory devices 104. As used herein, a codeword may refer to information that may be used to encode and correct errors in data stored on one or more flash memory devices 104.

The SSD controller 102 includes a data storage module 110, a status module 112, a read module 114, a decode module 116, a write module 118, a control module 120, and an ML module 122. The control module 120 may be coupled to the data storage module 110, the status module 112, the read module 114, the decode module 116, the write module 118, and the ML module 122. The status module 112 may be coupled to the data storage module 110, the read module 114, the decode module 116, the write module 118, the control module 120, and the ML module 122. The data storage module 110 may store configuration files associated with the ML module 122 and/or a TVSO selection table, among other examples. A TVSO selection table may be coupled to the read module 114. A TVSO selection table may include one or more indexes and corresponding TVSO values to be used in performing reads (e.g., an index corresponding to a block, a wordline, or a page and TVSO values for each threshold voltage region required to perform a read).

The read module 114 may be coupled to the control module 120, the ML module 122, and the decode module 116. The control module 120 may be coupled to the decode module 116, the ML module 122, and the data storage module 110. The ML module 122 may be coupled to data storage module 110 such that configuration files can be loaded thereon. In some examples, the ML module 122 may include a neural processing module such as, for example, a specialized hardware module (e.g., a specialized configurable accelerator) specifically configured to perform a neural network operation, sometimes referred to as a neural network engine (e.g., a programmable logic circuit). In some examples, the ML module 122 may include firmware (e.g., a processor and software for performing ML operations).

In some implementations, the SSD controller 102 may be an integrated circuit device and some or all of the modules 112, 114, 116, 118, 120, and 122 may include circuits that may be dedicated circuits for performing operations, and some or all of modules 112, 114, 116, 118, 120, and 122 may be firmware that include instructions that are performed on one or more processors for performing operations of the SSD controller 102, with the instructions stored in registers of one or more of modules 112, 114, 116, 118, 120, and 122 and/or stored in the data storage module 110 or the memory device 108. In some embodiments, some of all of modules 112, 114, 116, 118, 120, and 122 may include processors for performing instructions and one or more firmware image may be loaded into the SSD controller 102 (e.g., through the host connector receptacle 106) prior to operation of the SSD controller 102. The firmware image may include instructions to be performed by one or more of modules 112, 114, 116, 118, 120, and 122. Each flash memory device 104 may be a packaged semiconductor die or “chip” that is coupled to the SSD controller 102 by conductive pathways that couple instructions, data, and other information between each flash memory device 104 and the SSD controller 102.

A flash memory device 104 may include a VB 124. The VB 124 is a collection of blocks (e.g., memory blocks) 126 across multiple LUNs 128. A virtual wordline 130 is illustrated as a row of blocks 126. The VB 124 may include multiple channels 132, which may facilitate parallel data transfer operations. Each channel may be connected to multiple targets 134, which in turn are connected to multiple LUNs 128, forming a hierarchical structure that allows for efficient data management and access. In some implementations, a block 126 may refer to a basic unit of erase operations in NAND flash memory. For example, a block may typically contain 128 or 256 or more pages, with each page capable of storing several kilobytes of data.

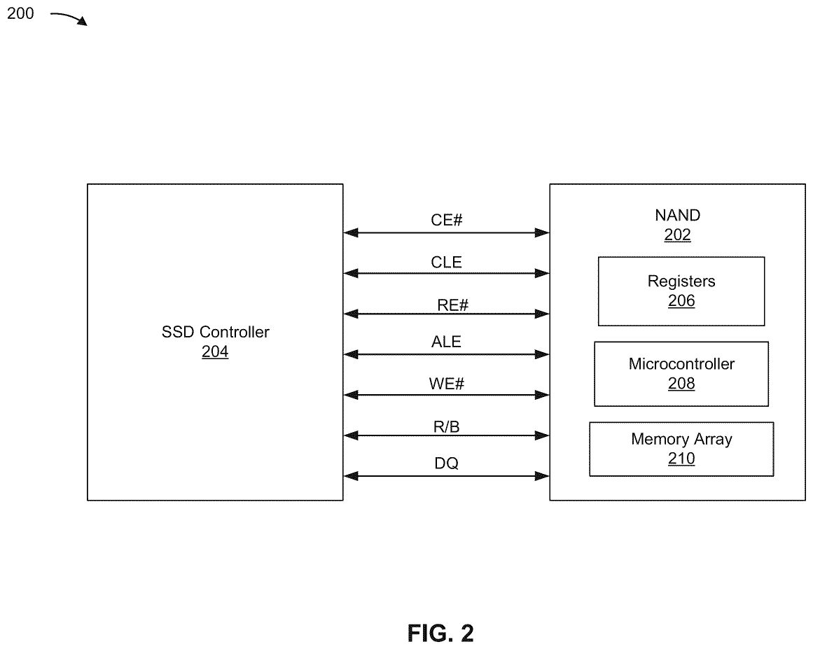

FIG. 2 is a block diagram showing another example of an SSD 200, in accordance with the present disclosure. In the embodiment shown in FIG. 2, a flash memory device 202 (e.g., a NAND device) is coupled to an SSD controller 204. The flash memory device 202 may be, be similar to, include, or be included in, the flash memory device 104 shown in FIG. 1. The SSD controller 204 may be, be similar to, include, or be included in, the SSD controller 102 shown in FIG. 1. The flash memory device 202 includes registers 206, a microcontroller 208, and a memory array 210, and is coupled to the SSD controller 204 by a chip enable signal line (CE #), a command latch enable signal line (CLE), a read enable signal line (RE #), an address latch enable signal line (ALE), a write enable signal line (WE #), a read/busy signal line (R/B) and input and output signal lines (DQ). Upon receiving a write instruction from a host computer, a write module (e.g., the write module 118 shown in FIG. 1) may be operable to encode received data into a codeword that is sent to the registers 206 along with a corresponding program instruction. The microcontroller 208 may be operable to perform the requested program instruction and retrieve the codeword from the registers 206 and store the codeword in the memory array 210 by programming cells of the memory array 210 (e.g., as a virtual page). The microcontroller 208 may also be operable to erase cells of the memory array 210.

In one example, the flash memory device 202 may include NAND memory cells that are organized into blocks and pages, with each block composed of NAND strings that share the same group of wordlines. Each virtual page is composed of cells belonging to the same wordline. However, in MLC, TLC, QLC, or PLC flash memory devices, multiple virtual pages may correspond with a single wordline. The number of virtual pages within each logical block (or virtual block) is typically a multiple of 16 (e.g. 64, 128). In some embodiments, a virtual page is the smallest addressable unit for reading from, and writing to, the NAND memory cells of the flash memory device 202 and a logical block is the smallest erasable unit. However, it is appreciated that in various embodiments, programming less than an entire virtual page may be possible, depending on the structure of the NAND array. Though the flash memory device 202 is illustrated as being a NAND device, it is appreciated that the flash memory device 202 may be any type of memory storage device that uses a threshold voltage for reading memory cells of the flash memory device 202. The terms programming and writing are used interchangeably throughout this document.

In some examples, the SSD 200 may include multiple flash memory devices that are similar to the flash memory device 202. The flash memory devices may be SLC, MLC, TLC QLC, or PLC NAND devices. In various aspects, the flash memory devices may be capable of performing a wide range of threshold-voltage-shift reads, including reads specified by whole number offset values such as −n . . . −2, −1,0, +1, +2 . . . n without limitation. A block of a flash memory device 202 that has been erased and does not contain any programmed data may be referred to as a “free block.” When data is programmed into a free block, the block is then referred to as an “open block” until all pages of the block have been programmed. Once all pages of the open block have been programmed, the block is referred to as a “closed block” until it is again erased.

As described above, if VBs remain in an open state for extended periods without being programmed, they become susceptible to data retention degradation and erase bake conditions. This susceptibility can lead to increased error rates in both programmed and unprogrammed wordlines, potentially resulting in data loss or corruption. Firmware solutions often lack the sophistication to proactively assess and manage the health of these open VBs, leading to suboptimal utilization of storage resources and potentially reduced SSD lifespan.

Implementations of this disclosure address problems such as these by determining a health of a last programmed wordline of a virtual block during a bootup process of a storage device that includes the virtual block, determining a health of a next unprogrammed wordline of the virtual block during the bootup process, and programming additional user data on the virtual block after the bootup process based on the determined health of the last programmed wordline and the next unprogrammed wordline. The health of the last programmed wordline may be determined using a first machine learning (ML) model, while the health of the next unprogrammed wordline may be determined using a second ML model. This approach allows for proactive assessment and management of open virtual blocks, potentially reducing error rates and improving overall SSD reliability.

As used herein, the term “virtual block” may refer to a collection of blocks across multiple LUNs in a solid-state drive. The term “wordline” may refer to a row of memory cells in a NAND flash memory device, which may be programmed or read simultaneously. The term “bootup process” may refer to the initialization sequence that occurs when a storage device is powered on or restarted. By determining the health of wordlines during this process, the system can make informed decisions about data programming without significantly impacting the time to ready (TTR) of the SSD.

Implementations of this disclosure may further address these problems by causing the virtual block to be in a closed state if the last programmed wordline or the next unprogrammed wordline is determined to be unhealthy. In such cases, a garbage collection operation may be performed to move valid data to a different virtual block, or a new virtual block may be opened for programming subsequent user data. This approach helps prevent data loss or corruption that might occur if programming were to continue on an unhealthy virtual block, while also optimizing the utilization of storage resources and potentially extending the lifespan of the SSD.

ML is a subset of artificial intelligence (AI) that involves the development of algorithms and statistical models enabling computers to perform tasks without explicit programming. ML leverages large datasets to identify patterns, make decisions, and improve over time based on experience. ML focuses on creating systems that can learn from data, adapt to new inputs, and generate predictions or actions.

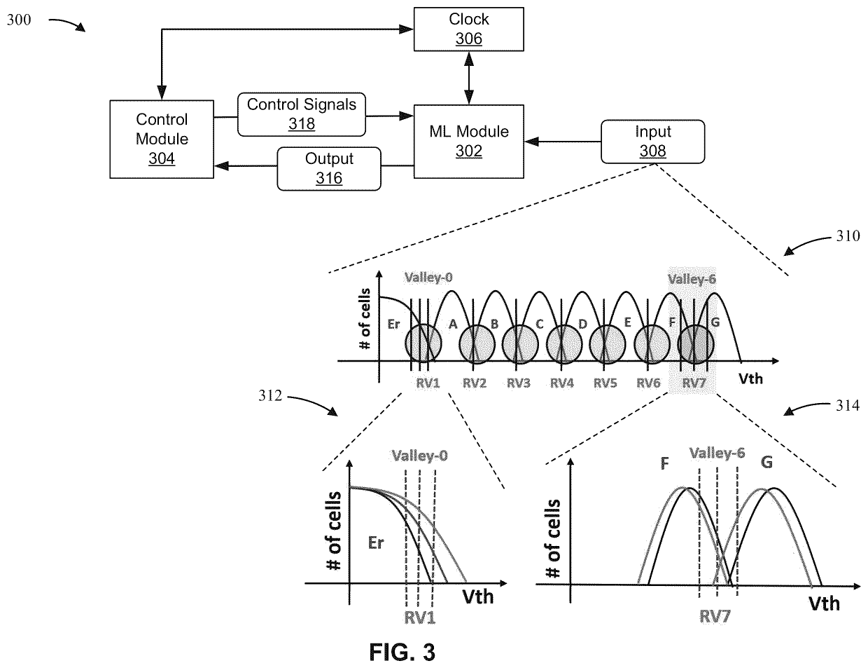

For example, an ML module (e.g., the ML module 122 shown in FIG. 1 or the ML module 302 shown in FIG. 3) may be or include one or more ML models, ML algorithms, and/or ML systems including combinations of ML algorithms and ML models. An ML module may be implemented on any number of different hardware devices and may include one or more ML models. ML is a field of study that gives computers the ability to perform certain tasks without being explicitly programmed to perform those tasks. In traditional computing, a programmer would encode instructions (e.g., to solve a quadratic equation using the quadratic formula), and the computer would perform those exact instructions. In contrast, in ML, a computer can be provided with examples and be trained to perform a task such as prediction or classification, without the programmer encoding explicit instructions for the task. ML explores the study and construction of algorithms, also referred to herein as tools, models, and/or components, which may learn from existing data and make predictions about new data. Such ML modules operate by building a model from example training data in order to make data-driven predictions or decisions expressed as outputs or assessments. Although example embodiments are presented with respect to a few ML models, the principles presented herein may be applied to other ML models. In some example embodiments, different ML models may be used. ML models may include, for example, K-means clustering models, linear regression models, Logistic Regression (LR) models, Naive-Bayes models, Random Forest (RF) regression models, gradient boost models, neural networks (NN), matrix factorization models, and/or Support Vector Machines (SVMs).

Two common types of problems in ML are classification problems and regression problems. Classification problems, also referred to as categorization problems, aim at classifying items into one of several category values (for example, is this object an apple or an orange). Regression algorithms aim at quantifying some items (for example, by providing a value that is a real number). The ML modules utilize the training data to find correlations among identified features that affect the outcome. The ML modules utilize features for analyzing the data to generate assessments. A feature is an individual measurable property of a phenomenon being observed. The concept of a feature is related to that of an explanatory variable used in statistical techniques such as linear regression. Choosing informative, discriminating, and independent features is important for effective operation of the ML in pattern recognition, classification, and regression. Features may be of different types, such as numeric features, strings, and graphs.

ML modules utilize the training data to find correlations among the identified features that affect the outcome or assessment. In some example embodiments, the training data includes labeled data, which is known data for one or more identified features and one or more outcomes. With the training data and the identified features, the ML module may be trained. The ML module appraises the value of the features as they correlate to the training data. The result of the training is the trained ML module. When the ML module is used to perform an assessment, new data is provided as an input to the trained ML module, and the ML module generates an assessment as output.

ML techniques train models to accurately make predictions on data fed into the models (e.g., what was said by a user in a given utterance; whether a noun is a person, place, or thing; what the weather will be like tomorrow). During a learning phase, the models are developed against a training dataset of inputs to optimize the models to correctly predict the output for a given input. Generally, the learning phase may be supervised, semi-supervised, or unsupervised; indicating a decreasing level to which the “correct” outputs are provided in correspondence to the training inputs. In a supervised learning phase, all of the outputs are provided to the model and the model is directed to develop a general rule or algorithm that maps the input to the output. In contrast, in an unsupervised learning phase, the desired output is not provided for the inputs so that the model may develop its own rules to discover relationships within the training dataset. In a semi-supervised learning phase, an incompletely labeled training set is provided, with some of the outputs known and some unknown for the training dataset.

Models may be run against a training dataset for several epochs (e.g., iterations), in

which the training dataset is repeatedly fed into the model to refine its results. For example, in a supervised learning phase, a model is developed to predict the output for a given set of inputs, and is evaluated over several epochs to more reliably provide the output that is specified as corresponding to the given input for the greatest number of inputs for the training dataset. In another example, for an unsupervised learning phase, a model is developed to cluster the dataset into n groups, and is evaluated over several epochs as to how consistently it places a given input into a given group and how reliably it produces the n desired clusters across each epoch.

Once an epoch is run, the models are evaluated and the values of their variables are adjusted to attempt to better refine the model in an iterative fashion. In various aspects, the evaluations are biased against false negatives, biased against false positives, or evenly biased with respect to the overall accuracy of the model. The values may be adjusted in several ways depending on the ML technique used. For example, in a genetic or evolutionary algorithm, the values for the models that are most successful in predicting the desired outputs are used to develop values for models to use during the subsequent epoch, which may include random variation/mutation to provide additional data points.

Each model develops a rule or algorithm over several epochs by varying the values of one or more variables affecting the inputs to more closely map to a desired result, but as the training dataset may be varied, and is preferably very large, perfect accuracy and precision may not be achievable. A number of epochs that make up a learning phase, therefore, may be set as a given number of trials or a fixed time/computing budget, or may be terminated before that number/budget is reached when the accuracy of a given model is high enough or low enough or an accuracy plateau has been reached. For example, if the training phase is designed to run n epochs and produce a model with at least 95% accuracy, and such a model is produced before the n^{th} epoch, the learning phase may end early and use the produced model satisfying the end-goal accuracy threshold. Similarly, if a given model is inaccurate enough to satisfy a random chance threshold (e.g., the model is only 55% accurate in determining true/false outputs for given inputs), the learning phase for that model may be terminated early, although other models in the learning phase may continue training. Similarly, when a given model continues to provide similar accuracy or vacillate in its results across multiple epochs—having reached a performance plateau—the learning phase for the given model may terminate before the epoch number/computing budget is reached.

Once the learning phase is complete, the models are finalized. In some example embodiments, models that are finalized are evaluated against testing criteria. In a first example, a testing dataset that includes known outputs for its inputs is fed into the finalized models to determine an accuracy of the model in handling data that it has not been trained on. In a second example, a false positive rate or false negative rate may be used to evaluate the models after finalization. In a third example, a delineation between data clustering is used to select a model that produces the clearest bounds for its clusters of data.

ML models may be implemented for use in a variety of use cases (e.g., language processing, image feature extraction, cyberthreat detection, or recommendation production), using a variety of approaches (e.g., supervised learning, unsupervised learning, or reinforcement learning), and in a variety of structures (e.g., a neural network, decision tree, linear regression, vector machine, Bayesian network, genetic algorithm, or deep learning system).

To reduce errors and conserve OP during an open block bake condition, when a VB is open for a particular number of hours without any write operation on the open block, implementations described herein performs a check for data retention degradation (DR), erase bake conditions, or a combination of data retention degradation and erase bake conditions on an immediate unprogrammed wordline every particular number of hours (or minutes). The particular number of hours are dependent on a type of the NAND and its susceptibility to DR and erase bake condition under an open block bake condition.

If the immediate unprogrammed WL is found to be not impacted by DR and erase bake conditions, then implementations described herein keep the VB open and continue writing user data to the open VB when the user data arrives. Because the VB is error prone, implementations described herein periodically check the immediate next unprogrammed wordline of the open VB for DR and an erase bake condition every particular number of hours.

If at any point of time, the immediate unprogrammed wordline of the open VB, which has not been written for the particular number of hours, is found to be impacted by DR, an erase bake condition, or a combination of DR and an erase bake condition, then the VB may be transitioned to a closed state. If new user data arrives to the SSD, a new VB may be placed in an open state to write the new user data. While examples herein refer to a particular number of hours, implementations described herein may be applicable to a particular number of minutes.

By using machine learning (ML) algorithms, implementations described herein provide an early detection of erase bake conditions on an open VB, thereby avoiding read and program errors, conserving OP, and maintaining sustained write performance and enhancing the lifetime of the SSD.

During bootup, after a power cycle it is not possible to know how long a block was open. In cases where the block has been open for a long time, the last written WL (WLₙ) and the next immediate unprogrammed WL (WLₙ₊₁) may be affected by DR with erase bake effects. Additionally, subsequent unprogrammed WLs (WLₙ₊₂ onwards) may be impacted by erase bake condition.

To address the DR condition on the last written wordline (WL), a new system FW algorithm uses an ML based solution to check the health of the last written WL during bootup for data integrity. If the last written WL is impacted by a DR issue, then the VB is closed and added to an urgent reclaim list. The urgent reclaim list (or urgent garbage collection) is the list of the VBs which are at the verge of correctable errors so if valid data from those VBs are not move to other good new VBs, then there might be chance of XOR recovery and in the worst case loss of the data. In general, it is better to prioritize the garbage collection on those VBs to avoid read latency issue (QOS issue). The system FW issues urgent garbage collection operations to move the valid data of the closed VB to a new VB. In some embodiments, ML can be used to avoid an urgent garbage collection operation on an open VB after a bootup process, thereby reducing TTR after the bootup process. This will also reduce re-erasing of erased WLs of the VB due to unnecessary garbage collection of partially written VBs.

If the last written WL is healthy, some embodiments further use ML models to check the data retention issue as well as erase bake effect on the immediate unprogrammed WL on all the open VBs after a bootup process. If the immediate unprogrammed WL is found to be unhealthy due to an open block bake condition, then the VB is closed and a new VB is opened for subsequent user data write. On the other hand, if the immediate unprogrammed WL is not found to be impacted by data retention or an open bake condition, the new system FW continues writing user data to the open VB.

Overall, implementations described herein provide several technical benefits, such as conserving OP by making optimum use of space, reducing the UBER rate by using ML techniques, and enhancing life of the SSD. The technical benefits are provided by avoiding unnecessary increase of P/E cycles during the bootup process due to garbage collection of partially written blocks.

FIG. 3 is a schematic block diagram showing an example 300 associated with using ML for determining health of wordlines for continued user data programming, in accordance with the present disclosure. The example 300 includes an ML module 302, a control module 304, a clock 306, an input 308, and voltage distributions 310, 312, and 314. The components of example 300 may be implemented within an SSD controller, such as the SSD controller 102 shown in FIG. 1 or the SSD controller 204 shown in FIG. 2.

The ML module 302 may include one or more ML models. In some implementations, the ML module 302 may incorporate neural networks, decision trees, or support vector machines, among other examples, to analyze wordline health data. The ML module 302 may be trained using training data that includes predetermined voltage distributions (also referred to as “predetermined voltage distributions”), which include historical threshold voltage distributions of one or more wordlines. The historical threshold voltage distributions may be part of the training data used to train the ML module 312 to determine an erase bake condition, data retention degradation, and a combination of the foregoing. The historical threshold voltage distributions may include a first threshold voltage distribution of an unprogrammed wordline subjected to data retention degradation, a second threshold voltage distribution of the unprogrammed wordline subjected to an erase bake condition, a third threshold voltage distribution of the unprogrammed wordline subjected to data retention degradation and an erase bake condition, and a fourth threshold voltage distribution of the unprogrammed wordline prior to being subjected to data retention degradation and/or an erase bake condition. The historical threshold voltage distributions may include similar threshold voltage distributions for one or more additional wordlines. In some situations, the ML module 302 may analyze the historical threshold voltage distributions to determine a first shift of the fourth threshold voltage distribution to the first threshold voltage distribution. The ML module 302 may analyze the historical threshold voltage distributions to determine a second shift of the fourth threshold voltage distribution to the second threshold voltage distribution. The ML module 302 may be provided information indicating that the first threshold voltage distribution is associated with data retention degradation, the second threshold voltage distribution is associated with the erase bake condition, the third threshold voltage distribution is associated with data retention degradation and an erase bake condition, and the fourth threshold voltage distribution is associated with a healthy unprogrammed wordline. Accordingly, the ML module 302 may determine that the first shift is indicative of data retention degradation and that the second shift is indicative of an erase bake condition. In some examples, different amounts of shifts may be indicative different measures of data retention degradation and/or of different measures of erase bake condition. Additionally, or alternatively, the ML module 302 may determine that a shape of the first threshold voltage distribution is indicative of data retention degradation and that a shape of the second threshold voltage distribution is indicative of an erase bake condition.

The control module 304 works in conjunction with the ML module 302 to manage the operations of the storage device. For instance, the control module 304 may interpret the output of the ML module 302 and issue commands to other parts of the storage device. The clock 306 provides timing information to the system 300. As used herein, the term “clock” may refer to a device that measures and indicates time. In this context, the clock 306 may be used to track the duration of various operations, such as how long a virtual block has been in an open state.

The input 308 represents the data fed into the ML module 302 for analysis. As used herein, the term “input” may refer to any data or signals that are entered into a system for processing. For example, the input 308 may include information about the last programmed wordline, the next unprogrammed wordline, or other relevant data from the storage device. In some implementations, for example, the input 308 may include voltage distributions. The voltage distribution 310 depicts the charge state distribution for cells in various charge states (labeled Er and A through G). In some situations, threshold voltages of different charge states may overlap. The threshold voltages of overlapped charge states are labeled RV1 through RV7. The voltage distribution 312 represents an example of how a voltage distribution of the erase state may shift over time as a result of an erase bake condition. As shown in FIG. 3, the voltage distribution 312 may indicate a shift of the voltage distribution 310 to the right (e.g., toward higher threshold voltages). The voltage distribution 312 may be referred to as an upper tail. An increase in the shift of the voltage distribution 310 to the right may indicate that an unprogrammed wordline is being increasingly subjected to an erase bake condition. The voltage distribution 312 may include the threshold voltages for erased cells. The voltage distribution 314 shows an example of how the programmed states may shift over time as a result of data retention degradation. The voltage distribution may include an overlap of threshold voltages of two charges. The overlap may be referred to as “valley-6” or RV7. As shown in FIG. 3, the voltage distribution 314 may indicate a shift of the voltage distribution 310 to the left (e.g., a shift of valley-6 toward lower threshold voltages). An increase in the shift of the voltage distribution 310 to the left may indicate that an unprogrammed wordline is being increasingly subjected to an erase bake condition.

In operation, the ML module 302 receives input 308, which may include data related to the wordlines (e.g., unprogrammed wordlines) being analyzed. The ML module 302 also receives timing information from the clock 306. The ML module 302 processes this data to assess the health of the wordlines. As explained herein, the data may include the voltage distribution 310, the voltage distribution 312, and the voltage distribution 314 (collectively “voltage distributions”). In some examples, the ML module 302 may compare the voltage distributions and the predetermined voltage distributions of the one or more wordlines of the training data. The one or more wordlines may be similar to the wordlines being analyzed. For example, the one or more wordlines may have similar (or same) physical characteristic, may have similar (or same) manufacturer, and/or may be part of similar (or same) storage devices. In some examples, the ML module 302 may compare the shift of the voltage distribution 314 and the first shift of the predetermined voltage distributions to determine whether the analyzed wordlines are being subjected to data retention degradation. For instance, the ML module 302 may determine that the analyzed wordlines are being subjected to data retention degradation if the shift of the voltage distribution 314 is similar to (or within a certain amount of) the first shift of the predetermined voltage. In some examples, the ML module 302 may compare a shape of the voltage distribution 314 and a shape of the first shift of the predetermined voltage distributions to determine whether the analyzed wordlines are being subjected to data retention degradation. For instance, the ML module 302 may determine that the analyzed wordlines are being subjected to data retention degradation if the shape of the voltage distribution 314 is similar to (or within a certain percentage) shape of the first shift. In some examples, the ML module 302 may compare a shape of the voltage distribution 312 and a shape of the second shift of the predetermined voltage distributions to determine whether the analyzed wordlines are being subjected to an erase bake condition. The ML module 302 generates an output 316 based on its analysis of the input data and voltage distributions (e.g., based on the comparisons). The output 316 may be a first value if the ML module 302 determines that the analyzed wordlines are being subjected to an erase bake condition a certain percentage. The output 316 may be a second value if the ML module 302 determines that the analyzed wordlines are being subjected to data retention degradation. The output 316 may be a third value if the ML module 302 determines that the analyzed wordlines are being subjected to a combination of an erase bake combination and data retention degradation. In some examples, the output 316 may include additional values indicating different measures (or levels) data retention degradation and erase bake condition. This output 316 is provided to the control module 304. The control module 304 uses this information to make decisions about the health and usability of the wordlines. For example, the control module 304 may determine that the analyzed wordlines are subjected to an erase bake condition if the output 306 includes the first value. The control module 304 may determine that the analyzed wordlines are subjected to data retention degradation if the output 306 includes the second value. The control module 304 may determine that the analyzed wordlines are subjected to data retention and an erase bake condition if the output 306 includes the third value. The control module 304 generates control signals 318 based on the ML module's output and its own processing. These control signals 318 may be used to manage operations such as continuing to write data to a virtual block, closing a virtual block, or initiating garbage collection.

During a bootup process of the storage device, the ML module 302 may determine the health of a last unprogrammed wordline of a virtual block. As explained herein, the ML module 302 may analyze a threshold voltage distribution of the last unprogrammed wordline. For example, the ML module 302 may analyze a shift of an upper tail of the threshold voltage distribution, a shift of a valley-0 of the threshold voltage distribution, a shape of the upper tail, and/or a shape of the valley-0 to determine whether the last unprogrammed wordline is being subjected to data retention degradation and/or an erase bake condition, As used herein, the term “bootup process” may refer to the sequence of operations that initialize a device when it is powered on or restarted. For example, the ML module 302 may analyze the voltage distribution of the last programmed wordline to assess its health. Based on the health of the last programmed wordline, the system 300 may then determine the health of a next unprogrammed wordline of the virtual block. For instance, if the last programmed wordline shows signs of degradation, the ML module 302 may predict a higher likelihood of issues with the next unprogrammed wordline. As an example, the ML module 302 may compare the threshold voltage distribution to predetermined threshold voltage distributions. For instance, if the voltage distribution of an unprogrammed wordline has shifted beyond a certain percentage from its expected position, it may be considered impacted. In some implementations, the decision may use a scoring system that takes into account multiple factors, such as the extent of threshold voltage shift, the number of affected cells within a wordline, and the predicted impact on future read/write operations. The overall score may then be compared to a threshold to make the decision. In some cases, the ML models may take into account complex patterns and relationships in training data.

After the bootup process, the control module 304 may make decisions about programming additional user data on the virtual block. As used herein, the term “user data” may refer to information stored by a user or application, as opposed to system data used by the storage device itself. For example, if both the last programmed wordline and the next unprogrammed wordline are determined to be healthy, the control module 304 may allow programming of additional user data to proceed. In some cases, the ML module 302 may determine that a wordline is unhealthy. As used herein, the term “unhealthy” when applied to a wordline may refer to a condition where the wordline exhibits characteristics that suggest a higher likelihood of errors or failures. For instance, an unhealthy wordline may show signs of significant threshold voltage shifts or increased bit error rates.

If either the last programmed wordline or the next unprogrammed wordline is determined to be unhealthy, the control module 304 may cause the virtual block to be in a closed state. As used herein, the term “closed state” when applied to a virtual block may refer to a condition where no further data can be written to the block. For example, if the ML module 302 detects signs of severe degradation in a wordline, the control module 304 may issue a command to close the virtual block.

In some implementations, when a virtual block is closed due to an unhealthy condition of the last programmed wordlines, the control module 304 may initiate a garbage collection operation. As used herein, the term “garbage collection” may refer to a process of relocating valid data from one storage area to another to free up space and improve efficiency. For instance, the control module 304 may oversee the movement of valid data from the closed virtual block to a different, healthy virtual block.

In some implementations, the control module 304 may open a new virtual block for programming subsequent user data. As used herein, the term “open” when applied to a virtual block may refer to making the block available for writing new data. For example, if the current virtual block is closed due to health issues, the control module 304 may designate a new virtual block as open and direct future write operations to this new block.

The ML module 302 may employ different machine learning models for assessing the health of programmed and unprogrammed wordlines. For instance, a first ML model within the ML module 302 may be specialized for analyzing the characteristics of programmed wordlines, while a second ML model may be optimized for predicting the health of unprogrammed wordlines based on surrounding data.

In some implementations, the ML module 302 may incorporate additional sensors or data sources to enhance its wordline health assessment capabilities. For example, temperature sensors may be included to monitor thermal conditions that could affect wordline health or current sensors may be used to detect abnormal current flows that might indicate wordline degradation. The ML module 302 may also adapt its behavior based on the specific type of storage device or memory technology being used. For instance, in a storage device using TLC NAND flash memory, the ML module 302 may be trained on data specific to TLC characteristics, while a different configuration might be used for QLC or other memory types.

By utilizing ML techniques to assess wordline health and manage data programming, implementations described herein may provide an approach to maintaining data integrity and optimizing storage device performance. This approach allows for dynamic decision-making based on real-time health assessments, potentially extending the lifespan of the storage device and improving its overall reliability.

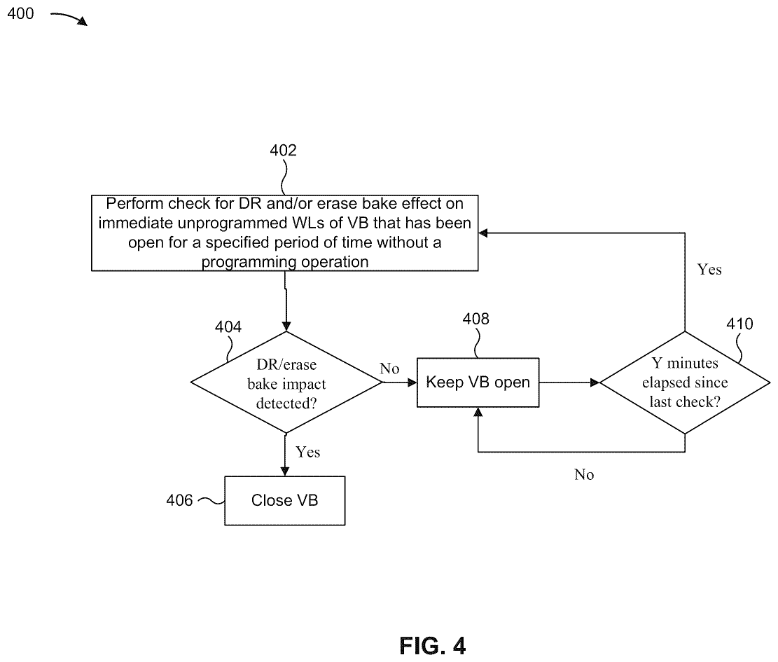

FIG. 4 is a flow chart showing an example of a process 400 for determining health of wordlines for continued user data programming, in accordance with the present disclosure. In some implementations, one or more process blocks of FIG. 4 may be performed by a controller of an SSD such as, for example, the SSD controller 102 shown in FIG. 1 or the SSD controller 204 shown in FIG. 2.

Block 402 involves performing a check for data retention (DR) and/or erase bake effects on immediate unprogrammed wordlines (WLs) of a VB that has been open for a specified time period without a programming operation (e.g., a NAND write activity). In some implementations, the check may be performed for all immediate unprogrammed wordlines of the VB. In some implementations, the check may be performed for one or more immediate unprogrammed wordlines of the VB. In some implementations, the check may be either NAND specific OR based on the pre-NAND characterization data. This check may be performed using various methods and techniques. In some aspects, the check may involve measuring the threshold voltage distributions of the unprogrammed wordlines. For example, the process 400 may use a series of read operations with different read voltages to determine if the threshold voltage distributions have shifted from their expected positions. In some cases, the check may utilize machine learning models trained on historical data to predict the likelihood of DR or erase bake effects based on various parameters such as the input 308, the time the VB has been open, the temperature history of the device, and the characteristics of neighboring programmed wordlines. Voltage distribution 310 may be a TLC distribution. Voltage distribution 312 may be related to the erase bake (wordline n+1 to wordline N) and may charge gain (wordline n+1, wordline n+2, and so on). Accordingly, the number of these wordlines will depend on the NAND type. Voltage distribution 314 may be the data retention signature which can be tested on the last written wordline.

Block 404 is a decision point where the process 400 determines if DR and/or erase bake impact is detected based on the check performed in block 402. In some implementations, the check for DR and/or erase bake effects may be performed for one immediate unprogrammed WLs of the VB. In some implementations, the check for DR and/or erase bake effects may be performed for a threshold number of immediate unprogrammed WLs. In some implementations, the check for DR and/or erase bake effects may be performed for all immediate unprogrammed WLs of the VB. This decision may be made using ML that evaluates the health of the virtual block using various criteria and thresholds. In some implementations, the decision may be based on a comparison of measured threshold voltage distributions to predetermined thresholds. For instance, if the voltage distribution of an unprogrammed wordline has shifted beyond a certain percentage from its expected position, it may be considered impacted. In some implementations, the decision may use a scoring system that takes into account multiple factors, such as the extent of threshold voltage shift, the number of affected cells within a wordline, and the predicted impact on future read/write operations. The overall score may then be compared to a threshold to make the decision. In some cases, the ML models may take into account complex patterns and relationships in the data.

If DR and/or erase bake impact is detected (as shown by the Yes branch from block 404), the process 400 moves to block 406, where the VB is closed. Closing the VB may involve several actions and considerations. In some aspects, closing the VB may involve marking it as unavailable for further write operations in a block management table or similar data structure. This ensures that no new data is written to potentially compromised wordlines. The process 400 may also initiate a data recovery operation for any valid data still present in the VB. This may involve reading the data using adjusted read voltages to compensate for the detected DR or erase bake effects, and then writing the recovered data to a new, healthy VB. In some implementations, closing the VB may trigger a background process 400 to perform a more thorough analysis of the block's condition, which may inform future decisions about whether the block can be reclaimed through remedial actions or should be permanently retired.

If no DR and/or erase bake impact is detected (as shown by the No branch from block 404), the process 400 continues to block 408, where the VB is kept open. Keeping the VB open allows for continued use of the block for write operations. In some aspects, keeping the VB open may involve updating metadata associated with the block to indicate that it has passed a health check. This information may be used to inform future scheduling decisions for write operations.

The process 400 may also adjust the priority or likelihood of the VB being selected for future write operations based on the results of the health check. For example, a VB that consistently passes health checks may be given higher priority for write operations compared to other open VBs. In some implementations, keeping the VB open may also involve adjusting operational parameters for future write operations to the block. For instance, the process 400 may slightly modify programming voltages or timing parameters to optimize for the current condition of the wordlines.

Block 410 is another decision point where the process 400 determines if a specified time (Y minutes) has elapsed since the last check. This time-based check ensures that the health of open VBs is periodically reassessed. In some aspects, the specified time Y may be a fixed value determined based on characterization of the specific type of NAND flash memory used in the device. For example, it might be set to 30 minutes for a particular grade of TLC NAND. Alternatively, the specified time Y may be dynamically adjusted based on various factors. For instance, it might be shortened if the device is operating at higher temperatures, or lengthened if previous checks have consistently shown no impact.

In some implementations, instead of a fixed time interval, the process 400 may use a more complex triggering mechanism for rechecks. This could involve monitoring write activity to the VB, tracking temperature changes, or using machine learning models to predict optimal times for rechecks based on device usage patterns and environmental conditions.

If the specified time has not elapsed (No branch), the process 400 returns to block 408 to keep the VB open. If the specified time has elapsed (Yes branch), the process 400 loops back to block 402 to perform another check on the unprogrammed wordlines.

This cyclical process allows for continuous monitoring of open VBs, enabling the storage device to adapt to changing conditions and maintain optimal performance and reliability over time. The process 400 provides a flexible framework that can be tailored to specific device characteristics and operational requirements, balancing the need for frequent health checks with the desire to minimize overhead and maximize performance.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

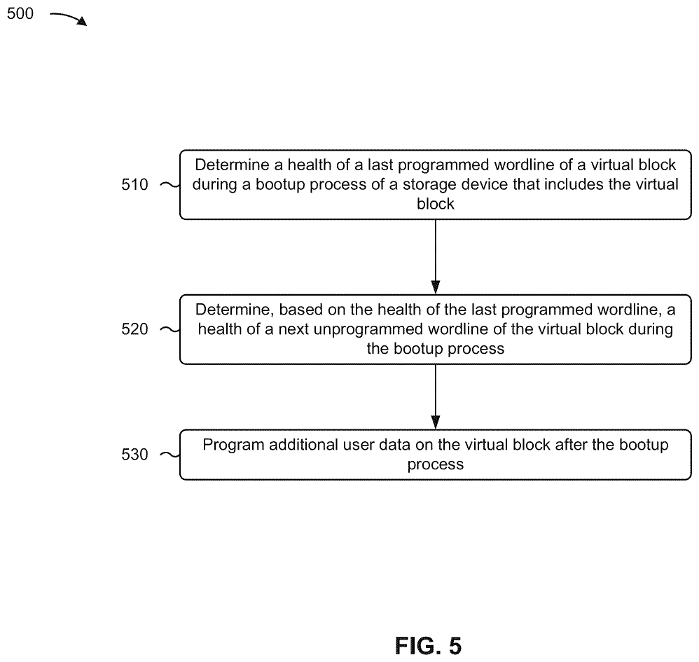

FIG. 5 is a flow chart showing another example of a process 500 for determining health of wordlines for continued user data programming, in accordance with the present disclosure. In some implementations, one or more process blocks of FIG. 5 may be performed by a controller of an SSD such as, for example, the SSD controller 102 shown in FIG. 1 or the SSD controller 204 shown in FIG. 2.

As shown in FIG. 5, process 500 may include determining a health of a last programmed wordline of a virtual block during a bootup process of a storage device that includes the virtual block, wherein the virtual block is an open state, wherein the virtual block includes user data, and wherein the health of the last programmed wordline is determined using a first machine learning model (block 510). For example, the controller may determine a health of a last programmed wordline of a virtual block during a bootup process of a storage device that includes the virtual block, wherein the virtual block is an open state, wherein the virtual block includes user data, and wherein the health of the last programmed wordline is determined using a first machine learning model, as described above. In some implementations, the virtual block is an open state, wherein the virtual block includes user data, and wherein the health of the last programmed wordline is determined using a first machine learning model.

As further shown in FIG. 5, process 500 may include determining, based on the health of the last programmed wordline, a health of a next unprogrammed wordline of the virtual block during the bootup process, wherein the health of the next unprogrammed wordline is determined using a second machine learning model (block 520). For example, the controller may determine, based on the health of the last programmed wordline, a health of a next unprogrammed wordline of the virtual block during the bootup process, wherein the health of the next unprogrammed wordline is determined using a second machine learning model, as described above. In some implementations, the health of the next unprogrammed wordline is determined using a second machine learning model.

As further shown in FIG. 5, process 500 may include programming additional user data on the virtual block after the bootup process, wherein the additional user data is programmed based on determining the health of the last programmed wordline and based on determining the health of the next unprogrammed wordline (block 530). For example, the controller may program additional user data on the virtual block after the bootup process, wherein the additional user data is programmed based on determining the health of the last programmed wordline and based on determining the health of the next unprogrammed wordline, as described above. In some implementations, the additional user data is programmed based on determining the health of the last programmed wordline and based on determining the health of the next unprogrammed wordline.

In some implementations, determining the health of the last programmed wordline comprises determining whether the last programmed wordline has been subjected to a data retention degradation or subjected to an erase bake effect.

In some implementations, determining the health of the next unprogrammed wordline comprises determining whether the next unprogrammed wordline has been subjected to a data retention degradation or subjected to an erase bake effect.

In some implementations, process 500 includes determining a health of a subsequent unprogrammed wordline that is subsequent to the next unprogrammed wordline, wherein the health of the subsequent unprogrammed wordline is determined during the bootup process.

In some implementations, process 500 includes determining that the last programmed wordline has been subjected to a data retention degradation and causing the virtual block to be in a closed state based on determining that the last programmed wordline has been subjected to the data retention degradation.

In some implementations, process 500 includes causing a garbage collection operation to be performed to move valid data of the virtual block, in the closed stated, to a different virtual block.

In some implementations, process 500 includes determining that the next unprogrammed wordline has been subjected to an open bake condition after programming the additional user data, and causing the virtual block to be in a closed state based on determining that the next unprogrammed wordline has been subjected to the open bake condition.

In some implementations, process 500 includes causing a new virtual block to be in an open state for programming of subsequent user data.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

In some implementations, a method includes determining a health of a last programmed wordline of a virtual block during a bootup process of a storage device that includes the virtual block, wherein the virtual block is an open state, wherein the virtual block includes user data, and wherein the health of the last programmed wordline is determined using a first machine learning model; determining, based on the health of the last programmed wordline, a health of a next unprogrammed wordline of the virtual block during the bootup process, wherein the health of the next unprogrammed wordline is determined using a second machine learning model; and programming additional user data on the virtual block after the bootup process, wherein the additional user data is programmed based on determining the health of the last programmed wordline and based on determining the health of the next unprogrammed wordline.

In some implementations, a system includes a controller to: determine a health of a last programmed wordline of a virtual block during a bootup process of a storage device that includes the virtual block, wherein the bootup process occurs after a power cycle, wherein the virtual block is an open state, and wherein the virtual block includes user data; determine, based on the health of the last programmed wordline, a health of a next unprogrammed wordline of the virtual block during the bootup process; and program additional user data on the virtual block after the bootup process, wherein the additional user data is programmed based on determining the health of the last programmed wordline and based on determining the health of the next unprogrammed wordline.

In some implementations, a non-transitory computer-readable medium stores a set of instructions, the set of instructions comprising: one or more instructions that, when executed by one or more processors of a controller, cause the controller to: determine a health of a last programmed wordline of a virtual block during a bootup process of a storage device that includes the virtual block, wherein the bootup process occurs after a power cycle, wherein the virtual block is an open state, and wherein the virtual block includes user data; determine, based on the health of the last programmed wordline, a health of a next unprogrammed wordline of the virtual block during the bootup process; and program additional user data on the virtual block after the bootup process, wherein the additional user data is programmed based on determining the health of the last programmed wordline and based on determining the health of the next unprogrammed wordline.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code-it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
determining a health of a last programmed wordline of a virtual block during a bootup process of a storage device that includes the virtual block,
wherein the virtual block is an open state,
wherein the virtual block includes user data, and
wherein the health of the last programmed wordline is determined using a first machine learning model;
determining, based on the health of the last programmed wordline, a health of a next unprogrammed wordline of the virtual block during the bootup process,
wherein the health of the next unprogrammed wordline is determined using a second machine learning model; and
programming additional user data on the virtual block after the bootup process,
wherein the additional user data is programmed based on determining the health of the last programmed wordline and based on determining the health of the next unprogrammed wordline.

2. The method of claim 1, wherein determining the health of the last programmed wordline comprises:
determining whether the last programmed wordline has been subjected to a data retention degradation or subjected to an erase bake effect.

3. The method of claim 2, wherein determining the health of the next unprogrammed wordline comprises:
determining whether the next unprogrammed wordline has been subjected to a data retention degradation or subjected to an erase bake effect.

4. The method of claim 1, comprising:
determining a health of a subsequent unprogrammed wordline that is subsequent to the next unprogrammed wordline,
wherein the health of the subsequent unprogrammed wordline is determined during the bootup process.

5. The method of claim 1, comprising:
determining that the last programmed wordline has been subjected to a data retention degradation; and
causing the virtual block to be in a closed state based on determining that the last programmed wordline has been subjected to the data retention degradation.

6. The method of claim 5, comprising:
causing a garbage collection operation to be performed to move valid data of the virtual block, in the closed stated, to a different virtual block.

7. The method of claim 1, comprising:
determining that the next unprogrammed wordline has been subjected to an open bake condition after programming the additional user data; and
causing the virtual block to be in a closed state based on determining that the next unprogrammed wordline has been subjected to the open bake condition.

8. The method of claim 7, comprising:
causing a new virtual block to be in an open state for programming of subsequent user data.

9. A system comprising:
a controller to:
determine a health of a last programmed wordline of a virtual block during a bootup process of a storage device that includes the virtual block,
wherein the bootup process occurs after a power cycle,
wherein the virtual block is an open state, and
wherein the virtual block includes user data;
determine, based on the health of the last programmed wordline, a health of a next unprogrammed wordline of the virtual block during the bootup process; and
program additional user data on the virtual block after the bootup process,
wherein the additional user data is programmed based on determining the health of the last programmed wordline and based on determining the health of the next unprogrammed wordline.

10. The system of claim 9, wherein, to determine the health of the last programmed wordline, the controller is to:
determine the health of the last programmed wordline using a first machine learning model.

11. The system of claim 10, wherein, to determine the health of the next unprogrammed wordline, the controller is to:
determine the health of the next unprogrammed wordline using a second machine learning model.

12. The system of claim 9, wherein, to program the additional user data on the virtual block, the controller is to:
determine that the last programmed wordline is healthy;
program the additional user data on the virtual block based on determining that the last programmed wordline is healthy;
determine that the next unprogrammed wordline is healthy; and
program the additional user data on the virtual block based on determining that the next unprogrammed wordline is healthy.

13. The system of claim 9, wherein the controller is to:
determine that the last programmed wordline is unhealthy;
cause the virtual block to be in a closed state based on determining that the last programmed wordline is unhealthy; and
cause a garbage collection operation to be performed to move valid data of the virtual block, in the closed stated, to a different virtual block.

14. The system of claim 13, wherein the controller is to:
determine that the next unprogrammed wordline is unhealthy after programming the additional user data;
cause the virtual block to be in a closed state based on determining that the next unprogrammed wordline is unhealthy; and
cause a new virtual block to be in an open state for programming of subsequent user data.

15. A non-transitory computer-readable medium storing a set of instructions, the set of instructions comprising:
one or more instructions that, when executed by one or more processors of a controller, cause the controller to:
determine a health of a last programmed wordline of a virtual block during a bootup process of a storage device that includes the virtual block,
wherein the bootup process occurs after a power cycle,
wherein the virtual block is an open state, and
wherein the virtual block includes user data;
determine, based on the health of the last programmed wordline, a health of a next unprogrammed wordline of the virtual block during the bootup process; and
program additional user data on the virtual block after the bootup process,
wherein the additional user data is programmed based on determining the health of the last programmed wordline and based on determining the health of the next unprogrammed wordline.

16. The non-transitory computer-readable medium of claim 15, wherein, to determine the health of the last programmed wordline, the controller is to:
determine the health of the last programmed wordline using a first machine learning model.

17. The non-transitory computer-readable medium of claim 15, wherein, to determine the health of the next unprogrammed wordline, the controller is to:
determine the health of the next unprogrammed wordline using a second machine learning model.

18. The non-transitory computer-readable medium of claim 15, wherein, to program the additional user data on the virtual block, the controller is to:
determine that the next unprogrammed wordline is healthy; and
program the additional user data on the virtual block based on determining that the next unprogrammed wordline is healthy.

19. The non-transitory computer-readable medium of claim 15, wherein the one or more instructions further cause the controller to:
determine that the last programmed wordline is unhealthy;
cause the virtual block to be in a closed state based on determining that the last programmed wordline is unhealthy; and
cause a garbage collection operation to be performed to move valid data of the virtual block, in the closed stated, to a different virtual block.

20. The non-transitory computer-readable medium of claim 19, wherein the one or more instructions further cause the controller to:
determine that the next unprogrammed wordline is unhealthy after programming the additional user data;
cause the virtual block to be in a closed state based on determining that the next unprogrammed wordline is unhealthy; and
cause a new virtual block to be in an open state for programming of subsequent user data.
